(19) United States
(12) Patent Application Publication
(10) Pub. No.: US 2009/0134455 A1
(43) Pub. Date: May 28, 2009

(54) SEMICONDUCTOR DEVICE AND MANUFACTURING METHOD

(75) Inventors: Shih-Fang Lin, Chiayi County (TW); Meng-Yen Hsieh, Miaoli County (TW); Yi-Tsung Jan, Taipei City (TW); Sung-Min Wei, Hsinchu City (TW); Chia-Yi Lee, Taipei City (TW); Chun-Yao Li, Taipei County (TW); Han-Lung Tsai, Changhua County (TW); Zhe-Xiong Wu, Hualien County (TW); Wen-Tsung Wang, Taipei City (TW)

Correspondence Address: QUINTERO LAW OFFICE, PC, 2210 MAIN STREET, SUITE 200, SANTA MONICA, CA, 90405, US

(73) Assignee: VANGUARD INTERNATIONAL SEMICONDUCTOR CORPORATION, Hsinchu (TW)

(21) Appl. No.: 11/946,016

(22) Filed: Nov. 27, 2007

(51) Int. Cl. H01L 29/78; H01L 21/336

(52) U.S. Cl. 257/327; 438/301; 257/E29.255; 257/E21.409

(57) ABSTRACT

A semiconductor device including a substrate, a first well, a second well, a gate, a first doped region, and a second doped region. The substrate includes a first conductive type. The first well includes a second conductive type and is formed in the substrate. The second well includes the second conductive type and is formed in the substrate. The gate is formed on the substrate and overlaps the first and the second wells. The first doped region includes the second conductive type. The first doped region is formed in the first well and self-aligned with the gate. The second doped region includes the second conductive type. The second doped region is formed in the second well and self-aligned with the gate. The gate, the first and the second doped regions constitute a transistor.

### BACKGROUND OF THE INVENTION

1. Field of the Invention

The invention relates to a semiconductor device and a manufacturing, and more particularly to a semiconductor device and a manufacturing method for reducing the channel length of a transistor.

2. Description of the Related Art

Due to the characteristics of semiconductor materials, semiconductor materials are utilized for manufacturing electronic devices; namely semiconductor devices. Since semiconductor devices belong to the solid state device field, the size of semiconductor devices can be reduced. Transistors are semiconductor amplifiers. The size of transistors is less than that of vacuum tubes with similar functions. The power consumption of transistors is less than vacuum tubes and the efficiency of transistors is higher than that of vacuum tubes. Thus, transistors have replaced vacuum tubes, and comprise a control function, an amplified function and a switch function.

The manufacturing technology of integrated circuits (ICs) has gradually developed along with technological advances. When ICs comprise one hundred, one thousand, or ten thousand transistors, ICs are called small scale integrated circuits (SSI), medium scale integrated circuits (MSI), or large scale integrated circuit (LSI), respectively. When the size of transistors is smaller, the ICs can comprise a larger amount of transistors.

### BRIEF SUMMARY OF THE INVENTION

Semiconductor devices are provided. An exemplary embodiment of a semiconductor device comprises a substrate, a first well, a second well, a gate, a first doped region, and a second doped region. The substrate comprises a first conductive type. The first well comprises a second conductive type and is formed in the substrate. The second well comprises the second conductive type and is formed in the substrate. The gate is formed on the substrate and overlaps the first and the second wells. The first doped region comprises the second conductive type. The first doped region is formed in the first well and self-aligned with the gate. The second doped region comprises the second conductive type. The second doped region is formed in the second well and self-aligned with the gate. The gate, the first and the second doped regions constitute a transistor.

Manufacturing methods are provided. An exemplary embodiment of a manufacturing method is described in the following. A substrate comprising a first conductive type is formed. A first well and a second well are formed in the substrate. Each of the first and the second wells comprises a second conductive. A gate is formed on the substrate. The gate overlaps the first and the second wells. The gate is utilized to serve as an implant mask such that a first doped region in the first well and a second doped region in the second well are formed. Each of the first and the second doped regions comprises the second conductive type.

A detailed description is given in the following embodiments with reference to the accompanying drawings.

### BRIEF DESCRIPTION OF THE DRAWINGS

The invention can be more fully understood by referring to the following detailed description and examples with references made to the accompanying drawings, wherein:

FIG. 1 is a schematic diagram of an exemplary embodiment of a semiconductor device;

FIG. 2 is a vertical view of the semiconductor device shown in FIG. 1; and

FIG. 3 is a flowchart of an exemplary embodiment of a manufacturing method.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

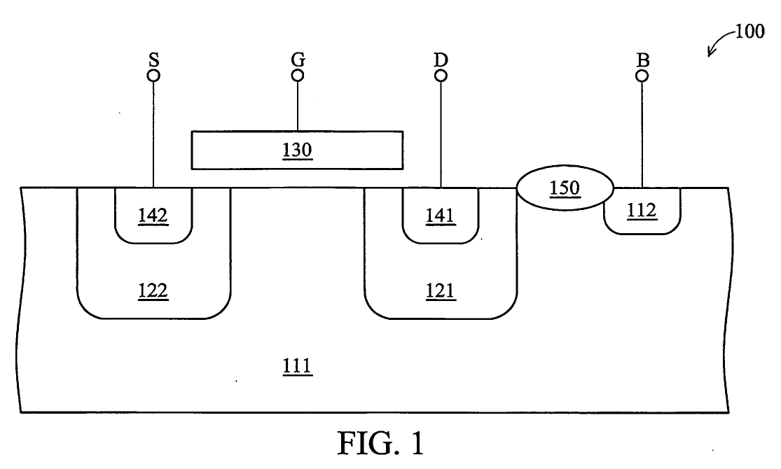

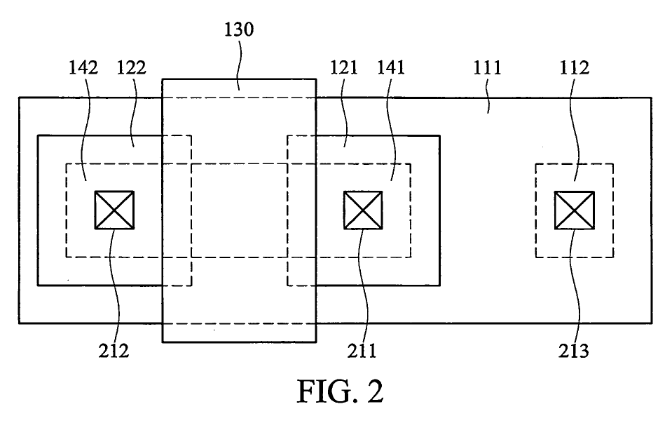

FIG. 1 is a schematic diagram of an exemplary embodiment of a semiconductor device. FIG. 2 is a vertical view of the semiconductor device shown in FIG. 1. Referring to FIG. 1, the semiconductor device 100 comprises a substrate 111, wells 121 and 122, a gate 130, and doped regions 141 and 142. The wells 121 and 122 are formed in the substrate 111. The gate 130 is formed on the substrate 111 and overlaps the wells 121 and 122. The doped region 141 is formed in the well 121 and self-aligned with the gate 130. The doped region 142 is formed in the well 122 and self-aligned with the gate 130. The gate 130, the doped regions 141 and 142 constitute a transistor. The doped region 141 serves as a drain of the transistor and the doped region 142 serves as a source of the transistor.

Referring to FIG. 2, symbol 211 represents a contact plug of the doped region 141 and symbol 212 represents a contact plug of the doped region 142. The doped regions 141 and 142 connect to an external circuit via the contact plugs 211 and 212 such that external voltage signals are transmitted to the doped regions 141 and 142. Since the gate 130 overlaps the wells 121 and 122, when the gate 130, the doped regions 141 and 142 respectively receive the suitable voltage signals, the voltage of the gate 130 corrects the electric-field distribution of the source and the drain to slow down a hot carrier effect (HCE).

Additionally, when the gate 130, the doped regions 141 and 142 respectively receive the suitable voltage signals, a channel is formed between the wells 121 and 122. Since the distance between the wells 121 and 122 is shorter, the length of the channel is reduced, thus, the size of the transistor is reduced. Because the length of the channel is shorter, the equivalent impedance between the drain and the source is reduced.

In this embodiment, when P-type dopant is doped in the substrate 111 and N-type dopant is doped in each of the wells 121, 122 and the doped regions 141 and 142, the conductive type of the substrate 111 is a P-type and the conductive type of each of the wells 121, 122 and the doped regions 141, 142 is an N-type. In some embodiments, when N-type dopant is doped in the substrate 111 and P-type dopant is doped in each of the wells 121, 122 and the doped regions 141 and 142, the conductive type of the substrate 111 is an N-type and the conductive type of each of the wells 121, 122 and the doped regions 141, 142 is a P-type.

In this embodiment, the doping concentration of the wells 121 and 122 is less than that of the doped regions 141 and 142, and the impedance of the wells 121 and 122 is less than that of the doped regions 141 and 142. Thus, the breakdown voltage between the wells 121, 122 and the substrate 111 is increased. When the breakdown voltage between the wells 121, 122 and the substrate 111 is higher, the transistor constituted by the gate 130, the doped regions 141 and 142 is capable of tolerating high voltage.

Additionally, the semiconductor device 100 further comprises a doped region 112 and field oxide 150. The field oxide 150 is formed between the well 121 and the doped region 112 for isolation. The doped region 111 is formed in the substrate 111 to serve as an electric-contact point of the substrate 111. In this embodiment, the conductive type of the doped region 112 is a P-type. A symbol 213 shown in FIG. 2 represents a contact plug of the doped region 112. The doped region 112 connects an external circuit via the contact plug 213.

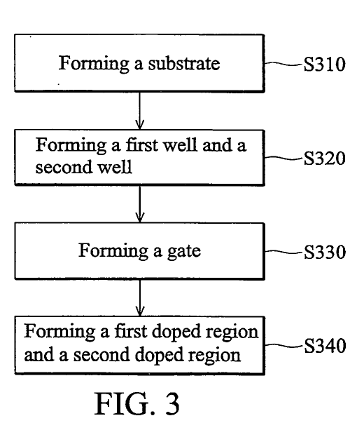

FIG. 3 is a flowchart of an exemplary embodiment of a manufacturing method. First, a substrate is formed (step S310). The substrate comprises a first conductive type. A first well and a second well are formed in the substrate (step S320). Each of the first and the second wells comprises a second conductive type. A gate is formed on the substrate (step S330). The gate overlaps the first and the second wells. The gate is utilized to serve as an implant mask such that a first doped region and a second doped are formed in the first and the second wells, respectively (step S340). In one embodiment, the first conductive type is a P-type and the second conductive type is an N-type. In some embodiments, the first conductive type is an N-type and the second conductive type is a P-type.

The gate, the first and the second doped regions constitutes a transistor. The first doped regions serve as a drain of the transistor. The second doped region serves as a source of the transistor. When the gate, the first and the second doped regions respectively receive the suitable voltage signals, a channel is formed between the first and the second wells. Since the forming step (step S330) of the gate is later than the forming step (step S320) of the first and the second wells, the length of the channel is determined by the distance between the first and the second wells. When the distance between the first and the second wells is shorter, the length of the channel is reduced. Thus, the equivalent impedance between the drain and the source of the transistor is reduced.

Additionally, since the gate overlaps the first and the second wells, when the gate, the first and the second doped regions respectively receive the suitable voltage signals, the voltage of the gate corrects the electric-field distribution of the source and the drain to slow down HCE. In some embodiments, a third doped region is further formed in the substrate. The conductive type of the third doped region is the same as the substrate serving as an electric-contact point of the substrate.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate comprising a first conductive type;
a first well comprising a second conductive type and forming in the substrate;
a second well comprising the second conductive type and forming in the substrate;
a gate forming on the substrate and overlapping the first and the second wells;
a first doped region comprising the second conductive type, forming in the first well, and self-aligned with the gate; and
a second doped region comprising the second conductive type, forming in the second well, and self-aligned with the gate, wherein the gate, the first and the second doped regions constitute a transistor.

2. The semiconductor device as claimed in claim 1, further comprising a third doped region comprising the first conductive type and forming in the substrate, wherein the third doped region serves as an electric-contact point of the substrate.

3. The semiconductor device as claimed in claim 2, wherein the first conductive type is a P-type and the second conductive type is an N-type.

4. The semiconductor device as claimed in claim 2, wherein the first conductive type is an N-type and the second conductive type is a P-type.

5. A manufacturing method, comprising:
forming a substrate comprising a first conductive type;
forming a first well and a second well in the substrate, wherein each of the first and the second wells comprises a second conductive;
forming a gate on the substrate, wherein the gate overlaps the first and the second wells; and
utilizing the gate to serve as an implant mask such that a first doped region in the first well and a second doped region in the second well are formed, wherein each of the first and the second doped regions comprises the second conductive type.

6. The manufacturing method as claimed in claim 6, further comprising: forming a third doped region in the substrate, wherein the third doped region comprises the first conductive type to serve as an electric-contact point of the substrate.

7. The manufacturing method as claimed in claim 6, wherein the first conductive type is a P-type and the second conductive type is an N-type.

8. The manufacturing method as claimed in claim 6, wherein the first conductive type is an N-type and the second conductive type is a P-type.
